(19) United States
(12) Patent Application Publication
(10) Pub. No.: US 2023/0231020 A1
(43) Pub. Date: Jul. 20, 2023

(54) FIELD PLATING AT SOURCE SIDE OF GATE BIAS MOSFETS TO PREVENT VT SHIFT

(71) Applicant: Texas Instruments Incorporated, Dallas, TX (US)

(72) Inventor: Ming-Yeh Chuang, McKinney, TX (US)

(21) Appl. No.: 17/577,133

(22) Filed: Jan. 17, 2022

(51) Int. Cl. H01L 29/40; H01L 29/78; H01L 29/06; H01L 29/10; H01L 21/765; H01L 29/66

(52) U.S. Cl. CPC H01L 29/402; H01L 29/7816; H01L 29/0649; H01L 29/1095; H01L 21/765; H01L 29/66681

(57) ABSTRACT

The present disclosure introduces a microelectronic device including a source side field plate in a microelectronic device. The microelectronic device may be configured as a metal oxide semiconductor (MOS) transistor, a laterally diffused metal oxide semiconductor (LDMOS) transistor, a drain extended metal oxide semiconductor (DEMOS) transistor, a bipolar junction transistor, a junction field effect transistor, a CMOS transistor, or a gated bipolar device. The source side field plate extends over the source region by a distance which is more than a quarter of the width of the source region. Transistors may suffer from Vt shifts during gate and drain stress over time. The source side field plate reduces the electric field of the transistor near the gate electrode corner on the source side of the transistor. The gate injection current on the source side and electron trapping in the gate oxide thereby reduced which reduces Vt shifts over time.

### FIELD

This disclosure relates to the field of microelectronic devices. More particularly, but not exclusively, this disclosure relates to source side field plates in MOSFETs.

### BACKGROUND

Field plates have been formed in microelectronic devices such as metal oxide semiconductor (MOS) transistors. Some methods of forming field plates do not protect transistors against shifts in transistor characteristics such as threshold voltage shifts (VT shift). Improvements in field plates into microelectronic devices are needed.

### SUMMARY

The present disclosure introduces a microelectronic device including a source side field plate in a transistor. The microelectronic device may be configured as a metal oxide semiconductor (MOS) transistor, a laterally diffused metal oxide semiconductor (LDMOS) transistor, a drain extended metal oxide semiconductor (DEMOS) transistor, a junction field effect transistor, a CMOS transistor, or a gated bipolar transistor. The source side field plate extends from the gate electrode more than a quarter of the distance over the source region. Transistors may suffer from Vt shifts during gate electrode stress over time. The source side field plate reduces the electric field of the transistor near the gate electrode corner on the source side of the transistor. The gate injection current on the source side and electron trapping in the gate oxide is thereby reduced which reduces Vt shifts over time.

### BRIEF DESCRIPTION OF THE VIEWS OF THE DRAWINGS

FIG. 1A through FIG. 1G are cross sections of an example microelectronic device with a source side field plate depicted in successive stages of an example method of formation.

FIG. 2 is a cross section of an example microelectronic device with a source side field plate within the PMD layer.

FIG. 3 is electrical data comparing the gate current at increasing voltage of a gate bias MOSFET with a field plate and without a field plate.

### DETAILED DESCRIPTION

The present disclosure is described with reference to the attached figures. The figures are not drawn to scale and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

In addition, although some of the embodiments illustrated herein are shown in two dimensional views with various regions having depth and width, it should be clearly understood that these regions are illustrations of only a portion of a device that is actually a three dimensional structure. Accordingly, these regions will have three dimensions, including length, width, and depth, when fabricated on an actual device. Moreover, while the present invention is illustrated by embodiments directed to active devices, it is not intended that these illustrations be a limitation on the scope or applicability of the present invention. It is not intended that the active devices of the present invention be limited to the physical structures illustrated. These structures are included to demonstrate the utility and application of the present invention to presently preferred embodiments.

It is noted that terms such as top, bottom, front, back, over, above, under, and below may be used in this disclosure. These terms should not be construed as limiting the position or orientation of a structure or element, but should be used to provide spatial relationship between structures or elements. Similarly, words such as “inward” and “outward” would refer to directions toward and away from, respectively, the geometric center of a device or area and designated parts thereof.

For the purposes of this disclosure, the term “lateral” refers to a direction parallel to a plane of the instant top surface of the microelectronic device. The term “vertical” is understood to refer to a direction perpendicular to the plane of the instant top surface of the microelectronic device. For the purposes of this disclosure, the term “conductive” is understood to mean “electrically conductive”.

A microelectronic device is formed in and on a substrate having a semiconductor material. The microelectronic device includes a field plate extending from the gate electrode at least a quarter of the way over the source region. The field plate is a conducting material, usually aluminum or copper but can be made from polysilicon. The field plate reduces electric fields near the corner of the gate electrode nearest the source region. Reducing the electric field near the corner of the gate electrode nearest the source region reduces gate injection current on the source side of the microelectronic device, reducing electrons trapped in the gate oxide. By reducing the electrons trapped in the gate oxide, shifts in threshold voltage (Vt) over time may be reduced. Vt shifts may be a reliability concern in microelectronic devices as they affect microelectronic device performance over time. This can be an especially important for microelectronic devices used in applications which have long use lifetimes in harsh conditions such as in the automotive industry and in factory automation applications. Source side field plates minimize such Vt shifts compared to microelectronic devices without field plates. Microelectronic devices with field plates may provide improved long term microelectronic device reliability.

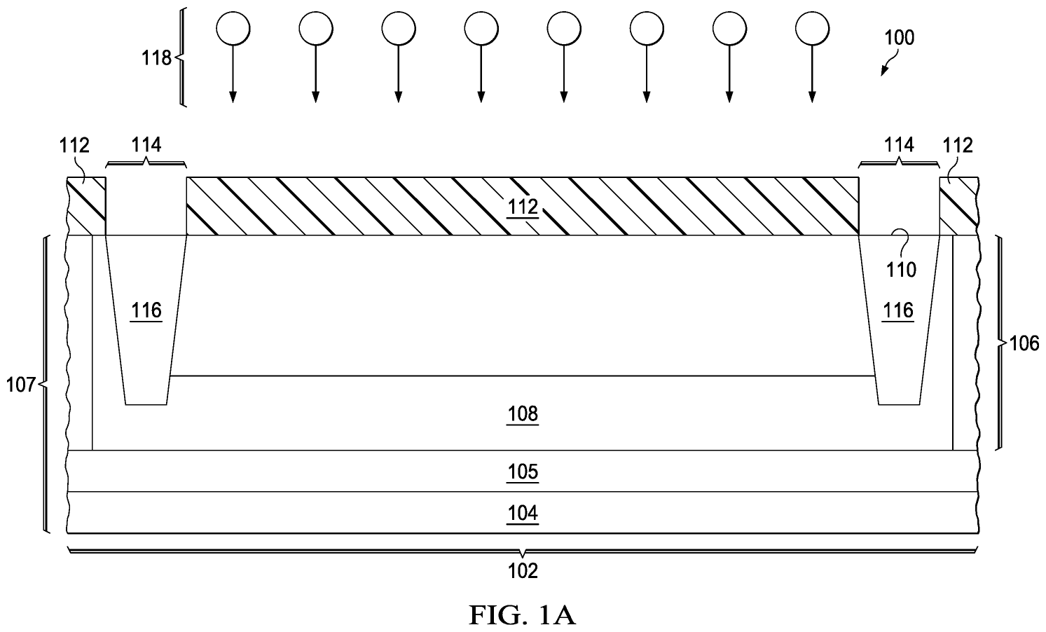

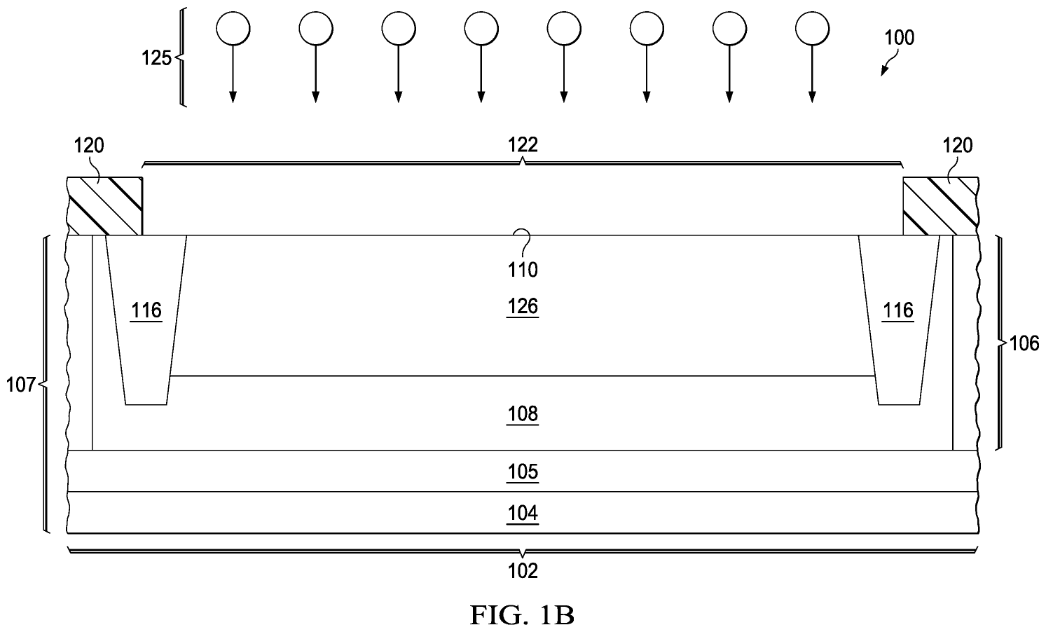

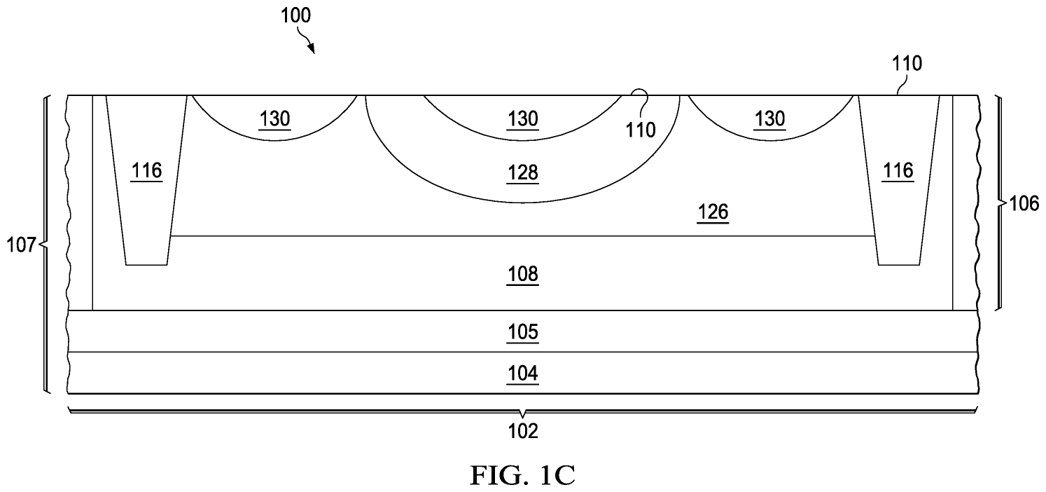

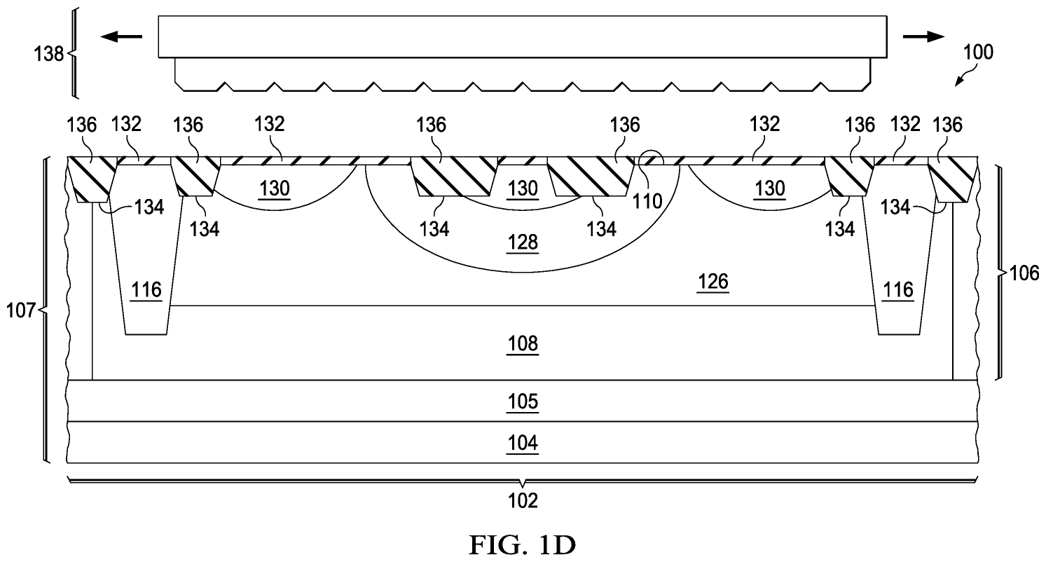

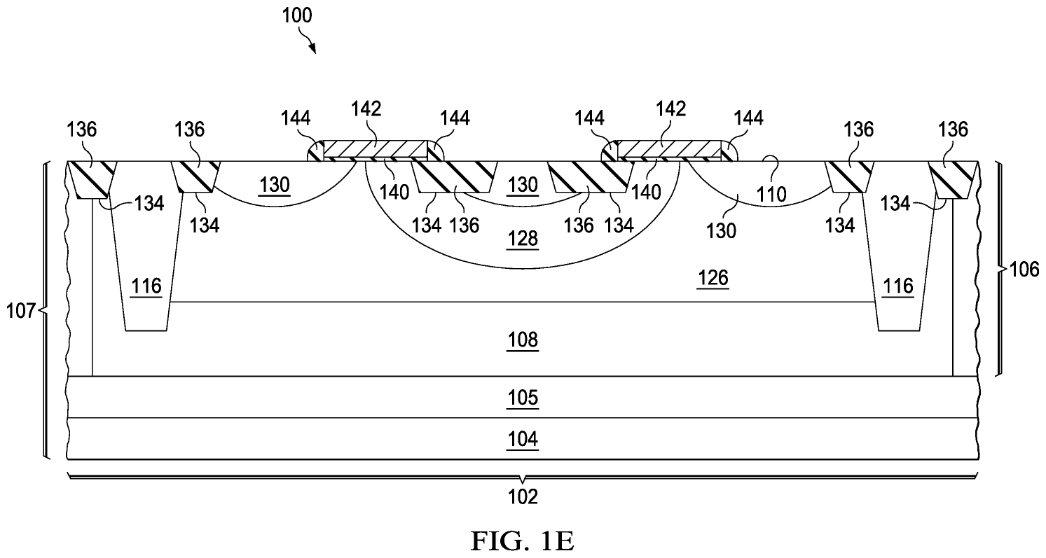

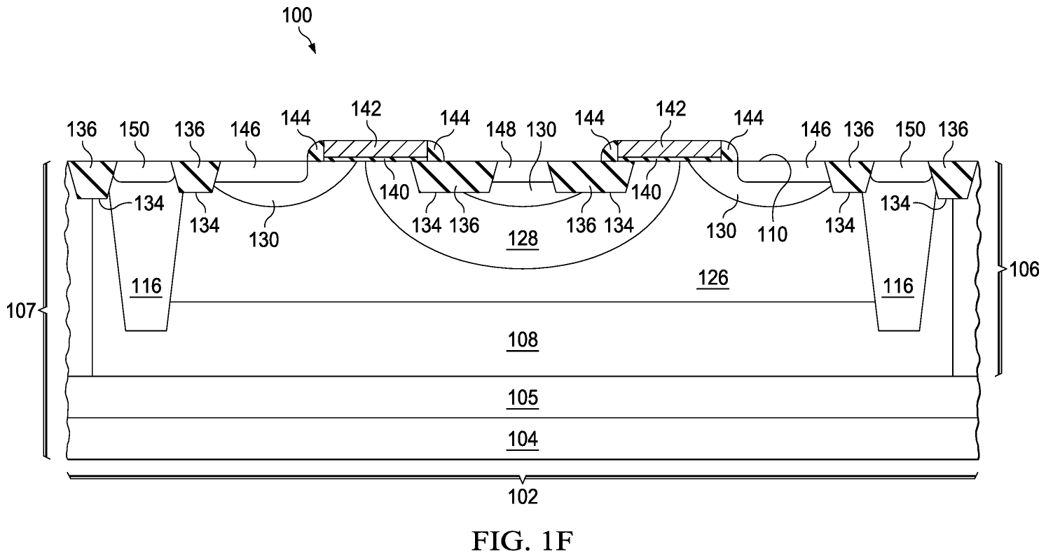

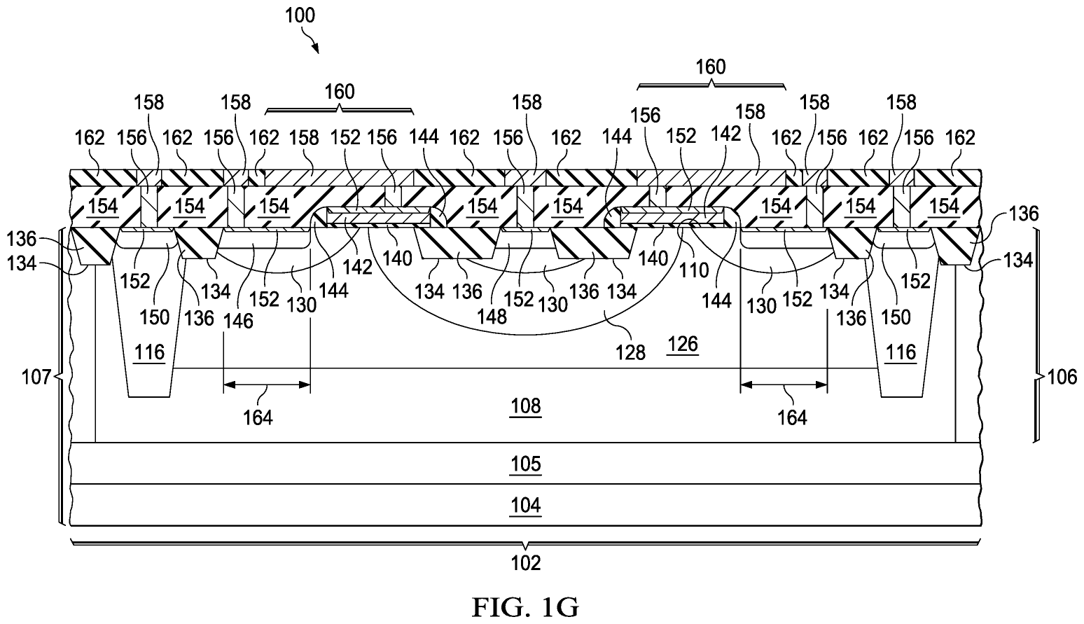

FIG. 1A through 1G are cross sections of the formation of an example microelectronic device 100 containing a DENMOS transistor 102. In this example, the first conductivity type is p-type and the second conductivity type is n-type. To form the corresponding DEPMOS transistor, the first conductivity type is n-type and the second conductivity type is p-type. Disclosed transistors may comprise a MOSFET that can generally be any MOSFET transistor controlled by a gate, or can be an insulated gate bipolar transistor (IGBT) which are generally known to be a semiconductor device having four alternating doped layers (P-N-P-N) that are controlled by a MOS gate structure without regenerative action. The MOSFET can comprise a symmetric or asymmetric drain-extended MOS transistor such as a drain extended metal oxide semiconductor (DEMOS), drain extended metal oxide transistor (DMOS), double diffused MOS (DDMOS) lateral double-diffused MOS (LDMOS), a double-diffused drain MOS (DDDMOS). Each of these device types can utilize an extended drain structure and its gate electrode (e.g. polysilicon) can be across the gate dielectric over the active area to a shallow trench isolation (STI) interface. Other transistor types which may use a source side field plate include a gated bipolar transistor, a junction field effect transistor (JFET), a metal oxide transistor (MOS) or a complementary metal oxide transistor (CMOS).

FIG. 1A shows the microelectronic device 100 containing a substrate 104. The substrate 104 may be, for example, part of a bulk semiconductor wafer, part of a semiconductor wafer with an epitaxial layer, part of a silicon-on-insulator (SOI) wafer, or other structure suitable for forming the microelectronic device 100. The substrate and the epitaxial region are referred to herein as the silicon 107. The substrate 104 may include a first buried layer 105 of the second conductivity type (n-type in this example) in the substrate 104. The n-type buried layer (NBL) 105 in the substrate and may be 2 microns to 10 microns thick, by way of example, and may have a dopant concentration of 1×10¹⁶ atoms/cm³ to 1×10¹⁷ atoms/cm³. After the deposition of the epitaxial layer 106 and a thermal drive (not specifically shown), a photomask (not specifically shown) is deposited and patterned with an opening which exposes regions of the epitaxial layer 106 where a buried layer implant (not specifically shown) of a first conductivity (p-type in this example) is to be implanted. A second buried layer 108, a p-type buried layer (PBL) 108 in this example is formed using a high energy p-type implant to add doping to the epitaxial layer 106. The p-type buried layer implant can comprise boron at a dose from 8×10¹³ cm⁻² to 5×10¹⁴ cm⁻² at an energy of 100 keV to 400 keV, the PBL layer 108 having an average dopant density greater than twice an average dopant density of the silicon between the buried layer and the top surface of the substrate. The PBL implant is followed by a thermal drive (not specifically shown). The dedicated thermal drive is optional as the activation of the PBL layer 108 can also be done during the same damage anneal as used after the NWELL region 128 and NDRIFT region 130 are formed (discussed in FIG. 1C). After the PBL layer 108 is formed, a photomask 112 is patterned with openings 114 which expose regions for a p-iso implant 118 in the silicon 107 to form a P-iso region 116. The p-iso implant 118 can comprise boron at a dose from 1×10¹³ cm⁻² to 1×10¹⁴ cm⁻² at an energy of 1000 keV to 2000 keV. The p-iso region 116 contacts the PBL layer 108 and the Pwell region 126 described in FIG. 1B to form the back gate for the DENMOS transistor 102.

Referring to FIG. 1B, A photomask 120 is deposited and patterned with an opening which exposes a region 122 of the silicon 107 where a Pwell implant 125 is to be implanted. A Pwell region 126 is formed using the Pwell implant 125 in the silicon 107. The Pwell implant 125 can comprise boron at a dose from 1×10¹² cm⁻² to 5×10¹³ cm⁻² with an energy of 30 keV to 2 mega-electron volts (MeV). After the Pwell implant 125 the photoresist is removed from the wafer, and a damage anneal may be used to activate the dopant.

Referring to FIG. 1C, a series of pattern and implant steps (not specifically shown) are used to define a well region of the second conductivity type (n-type in this example), NWELL region 128 in this example, and a drift region, NDRIFT region 130 in this example. An NWELL implant may comprise a phosphorous at a dose from 1×10¹² cm⁻² to 5×10¹² cm⁻² at an energy of 1000 keV to 3000 keV. to form the NWELL region 128. An NDRIFT implant may comprise phosphorus or arsenic at a dose from 2×10¹² cm⁻² to 1×10¹⁴ cm⁻² at an energy of 30 keV to 8 mega-electron volts (MeV) to form the NDRIFT region 130.

Referring to FIG. 1D, a CMP stop layer 132 may be formed over the top surface 110 of the silicon 107. The CMP stop layer 132 may be a layer of silicon dioxide, and silicon nitride. The silicon dioxide layer may be 5 nanometers to 20 nanometers thick, and may be formed by a thermal oxidation process. The silicon nitride layer may be 100 nanometers to 200 nanometers thick, and may be formed by an LPCVD process. Layers of other materials having a high CMP selectivity to silicon dioxide may be substituted for the silicon nitride layer of the CMP stop layer 132.

A field oxide layer 136 is formed. In one example, the field oxide layer 136 is a STI and formed using a field oxide mask (not specifically shown) that is formed over the CMP stop layer 132, and exposed to expose the CMP stop layer 132 in areas for a field oxide trench 134, in this example shown as a shallow trench known as shallow trench isolation (STI). The field oxide mask may include photoresist and may be formed by a photolithographic process. Subsequently, a field oxide trench 134 is formed in areas exposed by the field oxide mask to an STI etch (not specifically shown). The field oxide trench 134 may extend to a depth of 250 nanometers to 1 micron in the silicon 107, by way of example. After the field oxide trench 134 is formed, any remaining portion of the field oxide mask may be completely removed. Photoresist and other organic material in the field oxide mask may be removed by an oxygen plasma process, followed by a series of wet etch processes, including an aqueous mixture of sulfuring acid and hydrogen peroxide, an aqueous mixture of ammonium hydroxide and hydrogen peroxide, and an aqueous mixture of hydrochloric acid and hydrogen peroxide.

A field oxide layer 136 (non-conductive) is formed in the field oxide trench 134 and over the CMP stop layer 132. The field oxide layer 136 may include primarily silicon dioxide, or silicon dioxide-based dielectric material, formed by one or more CVD processes alternated with etch-back processes to provide complete filling of the field oxide trench 134. The field oxide layer 136 is planarized so that the field oxide layer 136 does not extend over the top surface 110 of the silicon 107 and the DENMOS transistor 102. The field oxide layer 136 may be planarized by a CMP process 138, as indicated in FIG. 1D. After the field oxide layer 136 is planarized, the CMP stop layer 132 is removed. The silicon nitride of the CMP stop layer 132 may be removed by a wet etch process using an aqueous solution of phosphoric acid at 140° C. to 170° C.

In another example, the field oxide layer 136 is formed using a local oxidation of silicon (LOCOS) process. Whether an STI process or a LOCOS process is used, the field oxide layer 136 forms field oxide isolation between the DENMOS transistor 102 and other components on the microelectronic device 100 where the field oxide layer 136 contacts the p-iso region 116. The field oxide layer 136 forms also a field oxide stress relief region for the DENMOS transistor 102 where the field oxide layer 136 contacts a gate dielectric layer 140 (shown in FIG. 1E).

Referring to FIG. 1E, the gate dielectric layer 140, a gate electrode 142 and a sidewall spacer 144 is formed. After the formation of the field oxide layer 136, the gate dielectric layer 140 is formed. Silicon dioxide in the gate dielectric layer 140 may be formed by thermal oxidation in an ambient containing oxygen or by a rapid thermal process. The ambient may also contain nitrogen. Nitrogen may be introduced into the gate dielectric layer 140 by exposure to nitrogen radicals in a decoupled plasma nitridation process or a remote plasma nitridation process, followed by an anneal process. High-k dielectric material, such as hafnium oxide or zirconium oxide, may be formed in the gate dielectric layer 140 by a sputter process, an atomic layer deposition (ALD) process, or a metalorganic chemical vapor deposition (MOCVD) process. For high voltage applications (greater than 20 V), the gate dielectric layer 140 may also be formed by a local oxidation of silicon (LOCOS) process.

After the formation of the gate dielectric layer 140, the gate electrode 142 is formed on the gate dielectric layer 140. Polysilicon in the gate electrode 142 may be formed by a plasma-enhanced chemical vapor deposition (PECVD) process using silane or disilane, followed by a reactive ion etch (RIE) process using an etch mask. A FUSI version of the gate electrode 142 may be formed by forming polysilicon on the gate dielectric layer 140, patterning the polysilicon, and forming a layer of metal such as titanium on the polysilicon. The layer of metal and the polysilicon are heated to form a metal silicide that extends to the gate dielectric layer 140. A metal version of the gate electrode 142 may be formed by a metal replacement gate process, in which patterned polysilicon is surrounded by dielectric material and removed by etching to form a gate cavity, exposing the gate dielectric layer 140. The one or more metals are formed on the gate dielectric layer 140 in the gate cavity. A plasma etch process (not specifically shown) is used to define the gate electrode 142.

After the formation of the gate dielectric layer 140 and the gate electrode 142, sidewall spacer 144 are formed on the gate electrode 142. The sidewall spacer 144 may be formed by forming one or more conformal layers of dielectric material over the gate electrode 142. The dielectric material is subsequently removed from horizontal surfaces, that is, surfaces generally parallel to the top surface 110 of the silicon 107, by an anisotropic etch process such as an RIE process, leaving the dielectric material on the vertical surfaces of the gate electrode 142.

Referring to FIG. 1F, after the sidewall spacer 144 formation, a source region 146 and a drain region 148 are formed by ion implantation. In this example, both the source and drain regions are n-type (second conductivity type). To form the source region 146 and drain region 148, a patterning step and an ion implantation step are used to implant the source region 146 in the NDRIFT region 130, and the drain region 148 in the NDRIFT region 130 within the NWELL region 128. The source region 146 and drain region 148 ion implant conditions may include one or more of phosphorus and arsenic as the source implant species. Phosphorus may be implanted with an energy between 15 KeV and 100 KeV, and a dose between 5×10¹³ cm⁻² to 5×10¹⁵ cm⁻². Arsenic may be implanted with an energy between 15 KeV and 150 KeV, and a dose between 1×10¹⁵ cm⁻² to 4×10¹⁵ cm². A p-type backgate region 150 is also implanted through an additional pattern and implant step. The p-type backgate region 150 ion implant conditions may include one or more of BF₂ or boron as the source implant species. BF₂ may be implanted with an energy between 3 KeV and 30 KeV, and a dose between 1×10¹⁵ cm² to 5×10¹⁵ cm⁻².

Referring to FIG. 1G, a metal silicide 152 may be formed on the microelectronic device 100 at the top surface 110, contacting the silicon 107. A layer of metal may be formed on the top surface 110 include platinum, tungsten, titanium, cobalt, nickel, chromium, or molybdenum, by way of example. A cap layer of titanium nitride or tantalum nitride may be formed over the layer of metal. Subsequently, the microelectronic device 100 is heated to react the layer of metal with the silicon 107, and the polysilicon of the gate electrode 142, to form the metal silicide 152. Unreacted metal in regions such as over the field oxide layer 136 is removed from the microelectronic device 100, leaving the metal silicide 152 in place. The unreacted metal may be removed by a wet etch process using an aqueous mixture of sulfuric acid and hydrogen peroxide, or an aqueous mixture of nitric acid and hydrochloric acid, by way of example. The metal silicide 152 may provide lower resistance for contacts 156 to the silicon 107 of the source region 146, the drain region 148 and the polysilicon of the gate electrode 142 compared to a microelectronic device 100 without metal silicide 152. Other methods of forming the metal silicide 152 are within the scope of this disclosure.

A pre metal dielectric (PMD) layer 154 is shown. The PMD layer 154 may include a PMD liner (not specifically shown) over the microelectronic device 100 which may be formed from one of silicon nitride, silicon oxynitride and silicon dioxide. The main dielectric sublayer of the PMD layer 154 is formed over the PMD liner if present. The main dielectric sublayer of the PMD layer 154 may be formed by one or more dielectric deposition processes, including a PECVD process using TEOS, a high-density plasma (HDP) process, or a high aspect ratio process (HARP) using TEOS and ozone, by way of example. The PMD layer 154 may be planarized by an oxide CMP process (not specifically shown). Other methods of forming the PMD layer 154 are within the scope of this disclosure.

Contacts 156 through the PMD layer 154 may be formed. The contacts 156 may be formed by patterning and etching holes through the PMD layer 154 and the PMD liner if present to expose the metal silicide 152. Contacts 156 may be filled by sputtering titanium to form a titanium adhesion layer, followed by forming a titanium nitride diffusion barrier using reactive sputtering or an ALD process. A tungsten core may then be formed by an MOCVD process using tungsten hexafluoride (WF₆) reduced by silane initially and hydrogen after a layer of tungsten is formed on the titanium nitride diffusion barrier. The tungsten, titanium nitride, and titanium are subsequently removed from a top surface of the PMD layer 154 by an etch process, a tungsten CMP process, or a combination of both (not specifically shown), leaving the contacts 156 extending to the top surface of the PMD layer 154. The contacts 156 may be formed by a selective tungsten deposition process which fills the contacts 156 with tungsten from the bottom up, forming the contacts 156 with a uniform composition of tungsten. Other methods of forming the contacts 156 are within the scope of this disclosure.

Interconnects 158 may be formed on the contacts 156. A key inventive aspect is the use of one of the interconnects 158 as a source side field plate 160. The source side field plate 160 is electrically connected to the gate electrode 142 through at least one of the contacts 156. The source side field plate 160 extends over the source region 146 by a distance which is more than a quarter of the width 164 of the source region 146.

In versions of this example in which the interconnects 158 have an etched aluminum structure, the interconnects 158 may be formed by depositing an adhesion layer, an aluminum layer, and an anti-reflection layer, and forming an etch mask (not explicitly shown) followed by an RIE process to etch the anti-reflection layer, the aluminum layer, and the adhesion layer where exposed by the etch mask, and subsequently removing the etch mask.

In versions of this example in which the interconnects 158 have a damascene structure, the interconnects 158 may be formed by forming an inter-metal dielectric (IMD) layer 162 on the PMD layer 154, and etching the interconnect trenches through the IMD layer 162 to expose the contacts 156. A barrier liner (not specifically shown) may be formed by sputtering tantalum onto the IMD layer 162 and the PMD layer 154 which is exposed and contacts 156, and forming tantalum nitride on the sputtered tantalum by an ALD process. The copper fill metal may be formed by sputtering a seed layer (not explicitly shown) of copper on the barrier liner, and electroplating copper on the seed layer to fill the interconnect trenches. The copper and barrier liner metal are subsequently removed from a top surface of the IMD layer 162 by a copper CMP process (not specifically shown).

In versions of this example in which the interconnects 158 have a plated structure, the interconnects 158 may be formed by sputtering the adhesion layer, containing titanium, on the PMD layer 154 and contacts 156, followed by sputtering a seed layer of copper on the adhesion layer. A plating mask is formed on the seed layer that exposes areas for the interconnects 158. The interconnects 158 are formed by electroplating copper on the seed layer where exposed by the plating mask. The plating mask is removed, and the seed layer and the adhesion layer are removed by wet etching between the interconnects 158. Other methods of forming the interconnects 158 are within the scope of this disclosure.

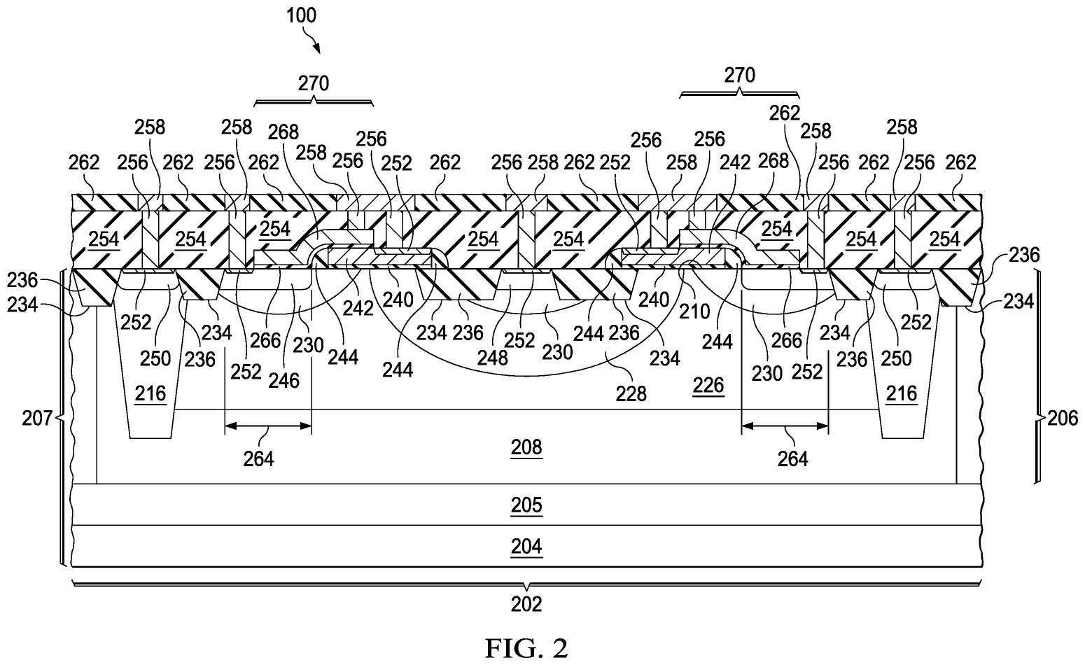

Referring to FIG. 2, a silicon nitride layer 266 or another insulating material may be formed followed by formation of a polysilicon layer 268 or other metal (before the PMD layer 254 is formed) as a source side field plate 270. The silicon nitride layer 266 is formed by depositing silicon nitride over the entire wafer, followed by depositing a polysilicon layer 268 over the entire wafer. A pattern and etch step (not specifically shown) are used to define the source side field plate 270. The source side field plate 270 is connected to the gate electrode 242 through contacts 256 and interconnects 258, and the polysilicon layer 268 of the source side field plate 270 is electrically isolated from the source region 246 by the silicon nitride layer 266 and the source side field plate 270 extends over the source region 246 by a distance which is more than a quarter of the width 264 of the source region 246. Other constructive elements of FIG. 2 are analogous to elements in FIG. 1G. Additionally, the semiconductor device 200 contains a substrate 204, an epitaxial layer 206, silicon 207, NBL 205, PBL 208, a top surface 210, a p-iso region 216, a Pwell region 226, a NWELL region 228, a NDRIFT region 230, a field oxide trench 234, a field oxide layer 236, a gate dielectric 240, a gate electrode 242, sidewall spacers 244, a source region 246, a drain region 248, a p-type back gate region 250, a metal silicide 252, a PMD layer 254, contacts 256, interconnects 258, a source side field plate 270, and an IMD layer 262.

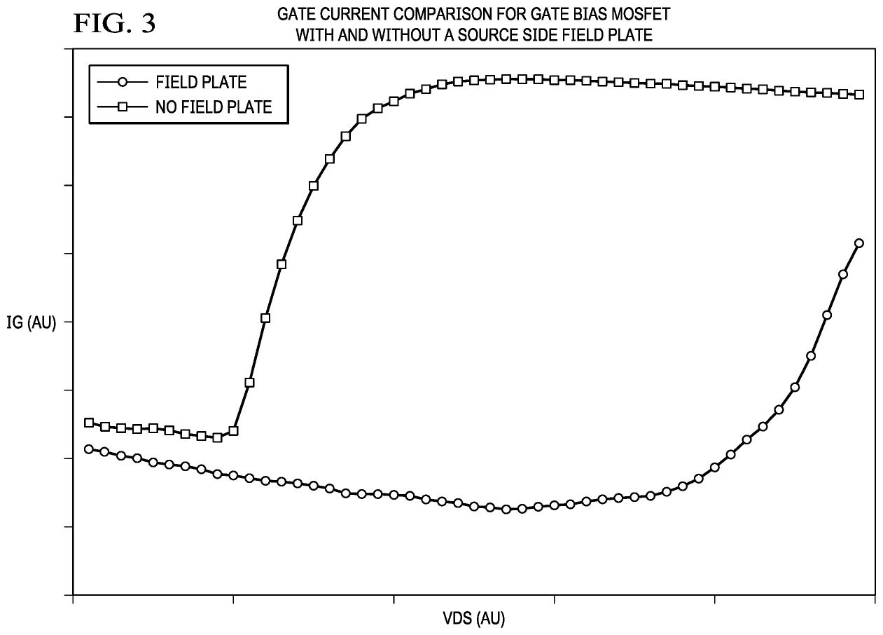

Referring to FIG. 3, electrical data comparing the gate current at increasing voltage of a gate bias MOSFET with a field plate 160 (as shown in FIG. 1G) and without a field plate (not specifically shown) are shown. The gate bias MOSFET without a field plate 160 shows an increase in gate current due to high electric field near the edge of the gate on the source side of the gate at relatively low voltages. The gate bias MOSFET with a field plate 160 reduces the electric field near edge of the gate on the source side, and the increase in gate current occurs at a much higher voltage than the gate bias MOSFET without the field plate 160. The electrical data curves have been smoothed to eliminate electrical noise from the test equipment.

While various embodiments of the present disclosure have been described above, it should be understood that they have been presented by way of example only and not limitation. Numerous changes to the disclosed embodiments can be made in accordance with the disclosure herein without departing from the spirit or scope of the disclosure. Thus, the breadth and scope of the present invention should not be limited by any of the above-described embodiments. Rather, the scope of the disclosure should be defined in accordance with the following claims and their equivalents.

What is claimed is:

1. A microelectronic device comprising:
a substrate, the substrate including silicon having a top surface;
a field oxide layer on the silicon;
a well of a first conductivity type in the silicon;
a gate dielectric on the silicon;
a gate electrode on the gate dielectric;
a source region and a drain region of a second conductivity type in the silicon;
a pre metal dielectric on the silicon and the gate electrode;
contacts to the source region, the drain region and the gate electrode; and
a source side field plate, the source side field plate being electrically connected to the gate electrode and extending over the source region by a distance more than a quarter of a width of the source region.

2. The microelectronic device of claim 1, wherein a transistor including the source-side field plate is selected from the group consisting of a drain extended metal oxide transistor (DMOS), a metal oxide semiconductor (MOS transistor), a laterally diffused metal oxide semiconductor (LDMOS) transistor, an insulated gate bipolar transistor (IGBT), double diffused MOS (DDMOS), a double-diffused drain MOS (DDDMOS) a junction field effect transistor (JFET), a complementary metal oxide transistor (CMOS), and a gated bipolar transistor.

3. The microelectronic device of claim 1, wherein the field oxide layer is selected from one of local oxidation of silicon (LOCOS) and shallow trench isolation (STI).

4. The microelectronic device of claim 1, wherein the source side field plate is in electrical contact with the gate electrode through one of the contacts, the source side field plate being an interconnect.

5. The microelectronic device of claim 1, wherein the source side field plate is in electrical contact with the gate electrode through one of the contacts to an interconnect and from the interconnect through another one of the contacts to the gate electrode, the source side field plate being within the pre metal dielectric.

6. The microelectronic device of claim 1, wherein a drift region of the second conductivity type is under the source region and a drift region of the second conductivity type is under the drain region.

7. The microelectronic device of claim 1, wherein a back gate of the first conductivity type is formed in contact with a field oxide layer.

8. The microelectronic device of claim 1, wherein the first conductivity type is n-type and the second conductivity type is p-type.

9. The microelectronic device of claim 1, wherein the source side field plate includes aluminum.

10. The microelectronic device of claim 1, wherein the source side field plate includes copper.

11. The microelectronic device of claim 1, wherein the source side field plate includes polysilicon.

12. A method of forming a microelectronic device comprising:
forming a well of a first conductivity type in a substrate including silicon, the silicon having a top surface;
forming a field oxide layer on the silicon;
forming a gate dielectric on the silicon;
forming a gate electrode on the gate dielectric;
forming a source region and a drain region of a second conductivity type in the silicon;
forming a pre metal dielectric;
forming contacts to the source region, the drain region and the gate electrode; and
forming a source side field plate, the source side field plate being electrically connected to the gate electrode and extending over the source region by a distance more than a quarter of a width of the source region.

13. The method of claim 12, further comprising forming the field oxide layer from one of local oxidation of silicon (LOCOS) and shallow trench isolation (STI).

14. The method of claim 12, wherein the source side field plate is formed in an interconnect, contacting the gate electrode through one of the contacts.

15. The method of claim 12, wherein the source side field plate is formed in the pre metal dielectric, contacting the gate through the contacts and interconnects.

16. The method of claim 12, further comprising forming a drift region of the second conductivity type under the source region and a drift region of the second conductivity type under the drain region.

17. The method of claim 12, further comprising forming a back gate of the first conductivity type in contact with the field oxide layer.

18. The method of claim 12, wherein the first conductivity type is p-type and the second conductivity type is n-type.

19. The method of claim 12, wherein the source side field plate is an interconnect.

20. The method of claim 12, wherein the source side field plate is polysilicon.
